(19) United States
(12) Patent Application Publication
(10) Pub. No.: US 2013/0038377 A1
(43) Pub. Date: Feb. 14, 2013

(54) POOLED-RESOURCE ARCHITECTURE WITH ASYNCHRONOUS PACKET-BASED COMMUNICATION

(71) Applicants: MARK WIGHT, Ottawa (CA); MOHAMAD SAMI MOHAMAD, Nepean (CA); ILIAN SVENDALINOV TZVETANOV, Ottawa (CA)

(72) Inventors: MARK WIGHT, Ottawa (CA); MOHAMAD SAMI MOHAMAD, Nepean (CA); ILIAN SVENDALINOV TZVETANOV, Ottawa (CA)

(73) Assignee: EXAR CORPORATION, Fremont, CA (US)

(21) Appl. No.: 13/209,129

(22) Filed: Aug. 12, 2011

(51) Int. Cl. H03K 17/00

(52) U.S. Cl. 327/403

(57) ABSTRACT

A chip includes a pool of blocks. Each block is adapted to implement a communication protocol. A cross-connect configurably connects between the blocks. A configured connection through the cross-connect between a sending block and a receiving block includes a lane with a toggle line and multiple data lines. The receiving block uses the toggle line to determine when valid data is on the data lines. The sending block and receiving block are on different clock domains.

### FIELD OF THE INVENTION

The present invention relates to multiplexers/demultiplexers for optical signals.

### BACKGROUND

The Optical Transport Network (OTN) is a set of Optical Network Elements connected by optical fiber links, able to provide functionality of transport, multiplexing, switching, management, supervision and survivability of optical channels carrying client signals. ITU-T G.709/Y.1331 describes interfaces for the Optical Transport Network (OTN).

The following Optical channel Transport Unit (OTU) signals are described in ITU-T G.709/Y.1331 (12/2009), OTU1, which can transport a constant bit rate client signal with bit rate close to 2.5 Gbit/s, OTU2, which can transport a constant bit rate client signal with bit rate close to 10 Gbit/s, OTU3, which can transport a constant bit rate client signal with bit rate around 40 Gbit/s and OTU4, which can transport a constant bit rate client signal with bit rate around 100 Gbit/s.

The OTU is an information structure into which ODU (Optical channel Data Unit) signals can be is mapped. ODUk defines different levels of bit rates like UTU.

Multiplexers/demultiplexers are used to put client signals into and off of optical signals. For example, the Multiplexer/demultiplexer can be used to put client signals into and off of OTU and ODU protocol signals. Such Multiplexers/demultiplexers can map between different client, OTU and ODU protocols.

### SUMMARY

A multiplexer/demultiplexer chip uses a cross-connect to send lanes between protocol blocks on the chip. The lanes include data lines and a toggle line. This allows the data to be sent between clock domains without using synchronous signals between the blocks. The use of the cross-connect for the lanes allows for routing of the lanes between different blocks. The blocks then implement the conversion between different protocols. The toggle line can be used to indicate valid data. Multiple lanes can be sent to and received by the blocks.

### BRIEF DESCRIPTION OF THE DRAWINGS

FIG. 1 shows an embodiment of the present invention that connects protocol blocks on a chip using a cross-connect.

FIG. 2 shows an exemplary lane structure.

FIGS. 3A-B show exemplary transfers of lanes through a cross-connect between sender and receiver blocks.

### DETAILED DESCRIPTION

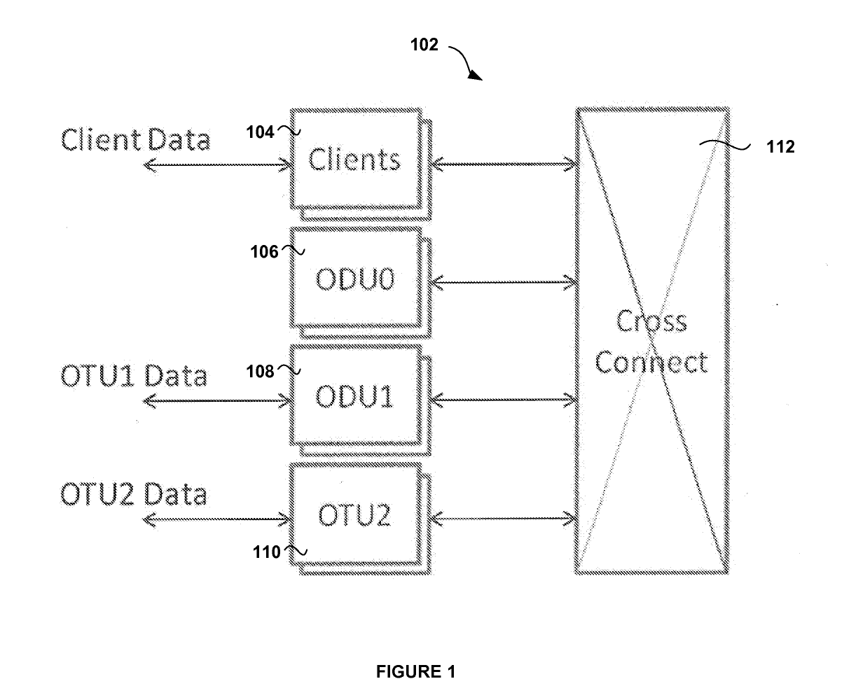

FIG. 1 shows chip 102 with a pool of blocks, including blocks 104, 106, 108 and 110. Each block is adapted to implement a communication protocol. In this example, blocks 104 implement a client protocol, such as Sonnet, Ethernet or the like. Blocks 104 can be configured to implement different protocols. Block 106 implements the ODU0 protocol. Block 108 implements the ODU1 protocol. Block 110 implements the OTU2 protocol. The blocks 104, 106, 108 and 110 can implement and multiplexing and demultiplexing functions with data sent through cross-connect 112. The cross-connect allows the chip to be configured to have the different functions.

A sender block converts the data in a first protocol to one or more lanes that are sent to a receiver block that converts the one or more lanes into a second protocol. Header information can be stripped from and added to the data as defined by the protocols. Cross-connect 112 configurably connects between the blocks. A connection through the cross-connect 112 between a sending block and a receiving block including one or more lanes. A lane includes a toggle line and multiple data lines. The receiving block uses the toggle line to determine when valid data is on the data lines. The sending block and receiving block can be on different clock domains and the use of the lanes allows data to be sent between the blocks asynchronously.

FIG. 1 shows an example of an OTN mapper device accepting some number of client signals in and supporting mapping of those clients into OTN levels 0 to 2. OTN allows clients to be mapped into any of these OTN levels directly, and then multiplexed into the higher levels. For example, a client may be mapped into an ODU0, two ODUs can be mapped into an ODU1, and 4 ODU1s can be mapped into an OTU2 to be transmitted out of the device. Alternatively, a client may be mapped directly into an ODU1 and transmitted out of the device as an OTU1 (note there is not an OTU0). Any of the supported mappings can be accomplished in the architecture described by the figure. Each block in the diagram represents a pool of resources, each of which can be connected via the cross-connect 112 to other elements to accomplish the desired configuration.

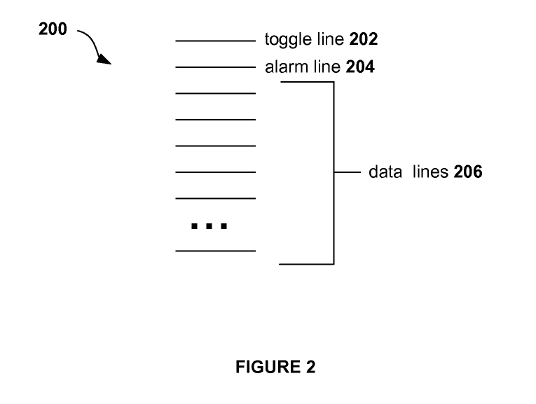

FIG. 2 shows an exemplary lane 200 with toggle line 202, alarm line 204 and data lines 206. In one embodiment, there are sixty-four data lines. The cross-connect connects lanes between a sender block and receiver block.

A transition of the toggle line indicates new data. The use of the toggle line helps avoid the need to synchronize a clock between the send and receiver block. The alarm line 204 can be used to indicate problems in the data transmission.

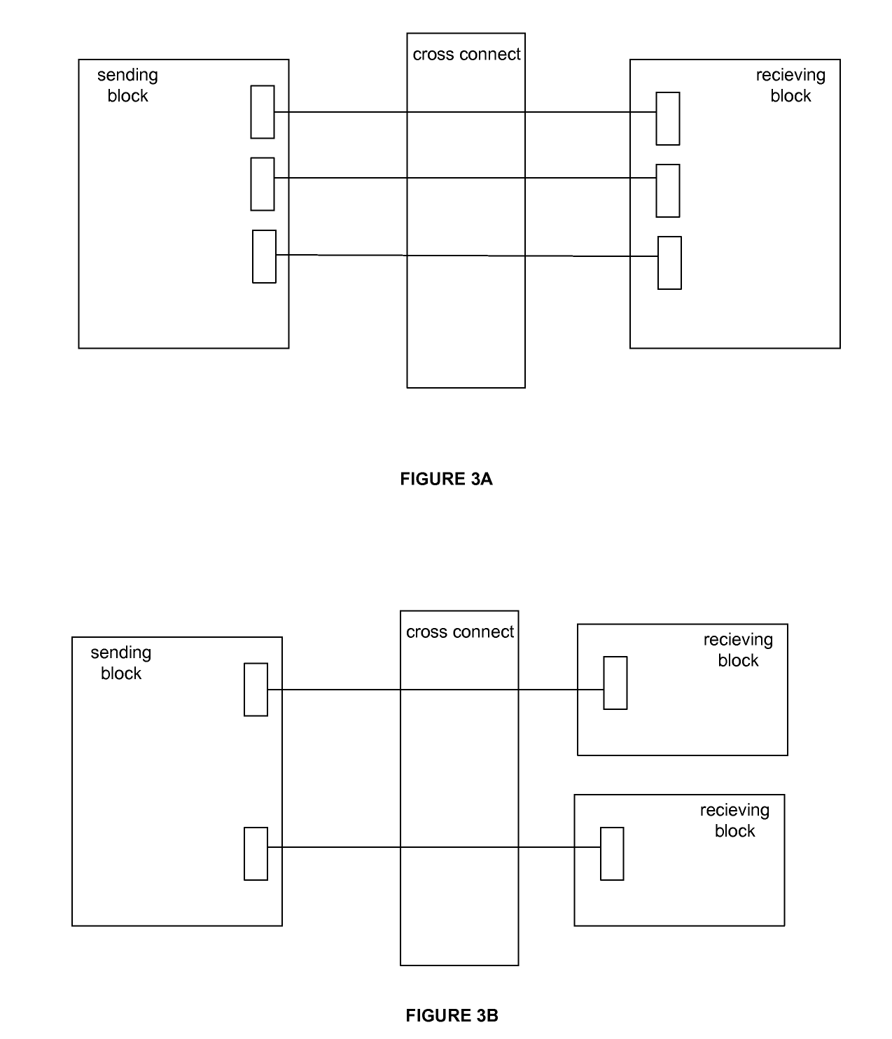

FIGS. 3A and 3B show exemplary lane connections between a sender and receiver blocks.

As shown in FIG. 3A, multiple lanes can be connected between the sending block and the receiving block through the cross-connect. The data can be obtained in a round robin fashion from the multiple lanes. The use of multiple lanes can reduce the required switching speed of the data and toggle on the lines of the lane.

As shown in FIG. 3B, the cross-connect can connect a single sending block to multiple receiving blocks. In this case, the sends block sender multiple lanes with each receiving block getting one of the sent lanes.

The design and implementation of large system-on-a-chip (SOC) devices have many challenges. The present invention describes an architecture that addresses three of these challenges, namely:

1. Inter-block interface complexity;

2. Inter-block timing/clocking; and

3. Physical area/size

Inter-block communication protocols are often block/function-specific, complicating inter-block connections with unnecessary signaling and making it difficult to connect blocks not originally intended to be connected. Adopting a common interface between all sub-blocks allows for less error-prone and more flexible communication at the top-level.

Despite efforts to reduce size, an SOC is typically a large device; therefore the device functionality is typically divided into sub-blocks. These sub-blocks are chosen to be more manageable sub-designs and are implemented independently from other sub-blocks with their own clocking structures and top-level interfaces. The sub-blocks must however, communicate with one another. The “normal” approach of using synchronous signaling may not be possible due to the challenges of balancing clock distribution between sub-blocks. A different approach not requiring balanced clocking between sub-blocks would therefore be beneficial.

The physical size of an SOC must be controlled since the device size is directly linked to cost and further complicates other design goals, therefore minimizing redundant logic to reduce area is highly desirable.

Often, when designing a data/telecom SOC device, all of the functionality for each data stream is implemented once per data stream, despite much of the functionality not being required in all configurations. For example, in an OTN mapper device required to map clients into an OTU2 via ODU0s and/or ODU1s, it would be common to implement the functionality for 8 ODUs and 4 ODU1s per OTU2, despite there being cases where none or few of the ODU0 or ODU1 functionality is required. This approach simplifies top-level design, but results in large amounts of unused logic under many configurations. This approach also potentially limits the flexibility of the device, as in the example given the user wanted to map a client into an OTU1 and not sue an OTU2. The proposed architecture employs pools of assignable device resources which can be inter-connected in a flexible way to achieve any combination of functionality utilizing only the functionality required for each configuration. Using this approach in the example given, the number of ODU0, ODU1 and OTU2 blocks would be determined by the number of clients supported. Each ODU0, ODU1 and OTU2 resource would be inter-connected by software to achieve the desired client configuration, achieving better flexibility with fewer resources.

Inter-connection of different resources is made possible by a standardized interface format. This architecture employs a packet-based interface with a simple structure. A packet element is composed of an enable toggle signal used to indicate new data is available, an alarm signal indicating there is a failure in the data path detected by the sender, plus a fixed-size data signal. This standardized interface allows any block to communicate with any other clock block without protocol-specific information being encoded into the interface structure.

Inter-connecting all of the resources would result in complex clocking requirements at the top-level if an improved method is not employed. This architecture employs an asynchronous, packet-based cross-connect which greatly simplifies the clocking requirements at the cross-connect and at the inter-connected blocks. The cross-connect itself may be a simple switch with no timing elements, or it may behave similarly to a receiver and use a store and forward architecture. The cross-connect need not have any knowledge of which blocks it is inter-connecting and require no balancing of clocks with the blocks connected to it. The clocking for the sending and receiving blocks are simplified by the enable toggle included in the interface packet's definition. The enable signal is toggled by the sender when there is new data to be transferred. The receiver detects transitions on the enable signal, using its own local clock and captures the alarm and data portion of the packet whenever a transition is detected. The receiver's clock frequency and phase need not be related to the sender's in any way, though there will be requirements for relative clock speeds, depending on the maximum data transfer rate. In order to deal with the delay involved in detecting the enable signal's transition, 3 packet lanes can be employed sequentially such that the sender does not have to wait until a transaction is complete before beginning another transaction. Instead, the sender sends data first to lane 1, followed by lane 2 and then lane 3. By the time the 3^{rd} transaction has been sent, the 1^{st} lane will be available for the next transaction.

The foregoing description of preferred embodiments of the present invention has been provided for the purposes of illustration and description. It is not intended to be exhaustive or to limit the invention to the precise forms disclosed. Many embodiments were chosen and described in order to best explain the principles of the invention and its practical application, thereby enabling others skilled in the art to understand the invention for various embodiments and with various modifications that are suited to the particular use contemplated. It is intended that the scope of the invention be defined by the claims and their equivalents.

1. A chip comprising:
a pool of blocks, each block adapted to implement a communication protocol; and
a cross-connect to configurably connect between the blocks, a configured connection through the cross-connect between a sending block and a receiving block including a lane with a toggle line and multiple data lines, wherein the receiving block uses the toggle line to determine when valid data is on the data lines, wherein the sending block and receiving block are on different clock domains.

2. The chip of claim 1, wherein multiple lanes are connected between the sending block and receiving block through the cross-connect.

3. The chip of claim 1, wherein the cross-connect connects a single sending block to multiple receiving blocks.

4. The chip of claim 3, wherein the sending block sends multiple lanes with each receiving block getting one of the sent lanes.

5. The chip of claim 1, wherein at least one of the blocks is an ODUk protocol block, where k=0,1,2,3,4,2e or flex.

6. The chip of claim 1, wherein at least one of the blocks is an OTUk protocol block, where k=0,1,2,3,4,2e or flex.

7. The chip of claim 1, wherein at least one of the blocks is a configurable client protocol block.

8. The chip of claim 1, wherein each lane includes an alarm line.

9. The chip of claim 1, wherein a transition of the toggle line indicates new data.

10. A chip comprising:
a pool of blocks, each block adapted to implement a communication protocol; and
a cross-connect to configurably connect between the blocks, a configured connection through the cross-connect between a sending block and a receiving block, is used to send data asynchronously and wherein the sending block and receiving block are on different clock domains.

11. The chip of lane 10, wherein a connection through the cross-connect between a sending block and a receiving block includes a lane with a toggle line and multiple data lines, and wherein the receiving block uses the toggle line to determine when valid data is on the data lines.

12. The chip of claim 11, wherein each lane includes an alarm line.

13. The chip of claim 11, wherein a transition of the toggle line indicates new data.

14. The chip of claim 11, wherein multiple lanes are connected between the sending block and receiving block through the cross-connect.

15. The chip of claim 10, wherein the cross-connect connects a single sending block to multiple receiving blocks.

16. The chip of claim 15, wherein the sending block sends multiple lanes with each receiving block getting one of the sent lanes.

17. The chip of claim 10, wherein at least one of the blocks is an ODUk protocol block, where k=0,1,2,3,4,2e or flex.

18. The chip of claim 10, wherein at least one of the blocks is an OTUk protocol block, where k=0,1,2,3,4,2e or flex.

19. The chip of claim 10, wherein at least one of the blocks is a configurable client protocol block.
